(19) United States
(12) Patent Application Publication
(10) Pub. No.: US 2019/0391608 A1
(43) Pub. Date: Dec. 26, 2019

(54) POWER MULTIPLEXER SYSTEM FOR CURRENT LOAD MIGRATION

(71) Applicant: QUALCOMM Incorporated, San Diego, CA (US)

(72) Inventors: Lipeng CAO, La Jolla, CA (US); Rajeev JAIN, San Diego, CA (US); Harshat PANT, San Diego, CA (US); Byron Glenn MURPHY, San Diego, CA (US)

(21) Appl. No.: 16/016,410

(22) Filed: Jun. 22, 2018

(51) Int. Cl. G05F 1/59

(52) U.S. Cl. CPC G05F 1/59; H03F 3/21

(57) ABSTRACT

A power multiplexer system including a power mux controller, wherein the power mux controller generates at least one non-regulated control signal; a regulator coupled to the power mux controller, wherein the regulator generates a reference voltage and wherein the reference voltage is used for generating a regulated control signal; and at least one power multiplexer tile coupled to the regulator, wherein each of the at least one power multiplexer tile includes a first branch comprising a first plurality of transistors and a second branch comprising a second plurality of transistors, and wherein enabling or disabling one or more of the first plurality of transistors is based on either the at least one non-regulated control signal or the regulated control signal.

### TECHNICAL FIELD

This disclosure relates generally to the field of power multiplexer, and, in particular, to power multiplexer system for current load migration.

### BACKGROUND

A power multiplexer may be used in an electronic circuit to manage multiple dc power supplies by migrating current among the dc power supplies. One issue with a power distribution network (PDN) which routes dc power from the dc power supplies to various circuit loads (e.g., integrated circuit intellectual property (IP) cores) is an initial current transient (e.g., in-rush current) during dc power supply switching. Various conventional solutions to the current transient problem have included negative consequences on overall circuit performance. Thus, an improved current management for a power multiplexer with multiple dc power supplies is desired.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides a power multiplexer system for voltage switching, current migration and/or rate control. Accordingly a power multiplexer system including a power mux controller, wherein the power mux controller generates at least one non-regulated control signal; a regulator coupled to the power mux controller, wherein the regulator generates a reference voltage and wherein the reference voltage is used for generating a regulated control signal; and at least one power multiplexer tile coupled to the regulator, wherein each of the at least one power multiplexer tile includes a first branch including a first plurality of transistors and a second branch including a second plurality of transistors, and wherein enabling or disabling one or more of the first plurality of transistors is based on either the at least one non-regulated control signal or the regulated control signal.

In one example, the at least one non-regulated control signal enables or disables one or more of the second plurality of transistors. In one example, the regulator includes a reference voltage generator and an amplifier. In one example, the reference voltage generator generates the reference voltage that serves as a first input to the amplifier. In one example, the reference voltage generator receives at least one mode control signal from the power mux controller. In one example, the amplifier generates the regulated control signal as an output. In one example, the at least one mode control signal includes one or more of the following: a regulator on/off control signal, a regulator bypass signal, and a reference voltage selection signal. In one example, the reference voltage is used to set a desired voltage level.

Another aspect of the disclosure provides a method for switching from a high voltage to a low voltage including setting a reference voltage to a first dc voltage; commencing regulation of one or more transistors of a first branch of a power multiplexer system and setting the power multiplexer system to a regulator mode; transitioning the reference voltage to a second dc voltage; enabling one or more transistors of a second branch of the power multiplexer system from a second dc voltage source at the second dc voltage to commence current migration from the first branch to the second branch; and transitioning from a regulated control signal to a non-regulated control signal for the one or more transistors of the first branch.

In one example, the method further includes enabling the first branch from a first dc voltage source at the first dc voltage to a current load with a regulator in an OFF state. In one example, the regulator generates the regulated control signal. In one example, the method further includes enabling the power multiplexer system in a regulator bypass mode. In one example, the power multiplexer system in the regulator bypass mode configures the regulator to turn ON without applying the regulated control signal to the one or more transistors of the first branch.

In one example, the method further includes transitioning from the non-regulated control signal to the regulated control signal for the one or more transistors of the first branch. In one example, the method further includes disabling the non-regulated control signal for the one or more transistors of the first branch. In one example, the method further includes disabling the regulator after current migration has completed.

In one example, the regulation of the one or more transistors of the first branch includes one or more of the following: voltage control, current migration, and rate control. In one example, the transitioning the reference voltage to the second dc voltage is bounded by a maximum absolute rate of change. In one example, the maximum absolute rate of change is a maximum absolute value of a first derivative of the reference voltage.

Another aspect of the disclosure provides a method for switching from a low voltage to a high voltage including enabling a regulator in a power multiplexer system and setting the power multiplexer system to a regulator mode; setting a reference voltage to a first dc voltage; disabling one or more transistors of a first branch of the power multiplexer system from the first dc voltage source to commence current migration from the first branch to a second branch of the power multiplexer system; transitioning from a non-regulated control signal to a regulated control signal for one or more transistors of the second branch; and transitioning the reference voltage from the first dc voltage to a second dc voltage.

In one example, the disabling the one or more transistors of the first branch is performed at a limited rate of change. In one example, the limited rate of change is a bounded absolute value of a first derivative of the current migration. In one example, the regulated control signal is generated by the regulator. In one example, the transitioning from the non-regulated control signal to the regulated control signal for the one or more transistors of the second branch includes selecting the regulated control signal from the regulator to control the one or more transistors of the second branch. In one example, the regulator mode includes one or more of the following: voltage control, current migration, and rate control.

In one example, the method further includes enabling the first branch from a first dc voltage source which generates the first dc voltage to a current load with the regulator in an OFF state. In one example, the method further includes setting the power multiplexer system to a regulator bypass mode and enabling the non-regulated control signal for the one or more transistors of the second branch. In one example, the method further includes transitioning from the regulated control signal to the non-regulated control signal for the one or more transistors of the second branch. In one example, the method further includes disabling the regulator after current migration has completed and enabling the second branch from the second dc voltage source at the second dc voltage to the current load with the regulator in the OFF state.

Another aspect of the disclosure provides a computer-readable medium storing computer executable code, operable on a device including at least one processor and at least one memory coupled to the at least one processor, wherein the at least one processor is configured to implement switching from a high voltage to a low voltage, the computer executable code including instructions for causing a computer to set a reference voltage to a first dc voltage; instructions for causing the computer to commence regulation of one or more transistors of a first branch of a power multiplexer system and setting the power multiplexer system to a regulator mode; instructions for causing the computer to transition the reference voltage to a second dc voltage; instructions for causing the computer to enable one or more transistors of a second branch of the power multiplexer system from a second dc voltage source at the second dc voltage to commence current migration from the first branch to the second branch; and instructions for causing the computer to transition from a regulated control signal to a non-regulated control signal for the one or more transistors of the first branch.

These and other aspects of the invention will become more fully understood upon a review of the detailed description, which follows. Other aspects, features, and implementations of the present invention will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates an example of a power multiplexer tile.

FIG. 2 illustrates an example of a power multiplexer system.

FIG. 3 illustrates an example of a flow diagram for switching from a high voltage to a low voltage.

FIG. 4 illustrates an example of a flow diagram for switching from a low voltage to a high voltage.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

In an electronic circuit, multiple dc power supplies may provide dc power for various current consumers (i.e., circuit loads). One type of circuit load is an integrated circuit (IC) which includes logic blocks (e.g., intellectual property (IP) cores). A power multiplexer (mux) may be used to select and manage the multiple dc power supplies by migrating large current among the power supplies. For example, a power distribution network (PDN) may be used to route dc power from the dc power supplies to the various circuit loads. In one example, in-rush current during power multiplexer switching between dc power supplies may incur in-rush current. In-rush current is an initial current transient which may be typically many times higher than the steady state current. In an example, selected transistors in the power multiplexer (e.g., strong p-type metal oxide semiconductor (PMOS) transistors) are disabled, which may reduce the current carrying capacity of the power multiplexer. Consequently, the circuit load needs to be reduced.

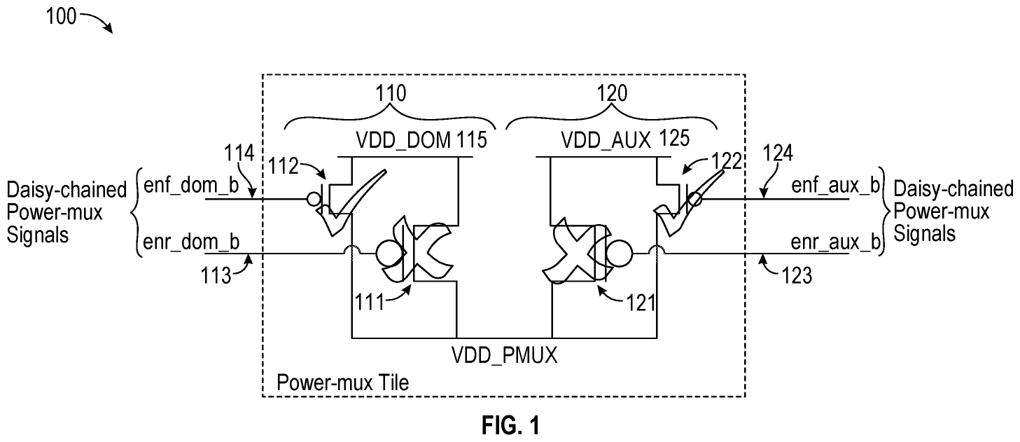

FIG. 1 illustrates an example of a power multiplexer tile 100. The power multiplexer tile 100 includes a first branch 110 (e.g., dominant branch) and a second branch 120 (e.g., auxiliary branch). The first branch 110, for example, may include a first type A transistor 111 (e.g., first strong transistor) and a first type B transistor 112 (e.g., first weak transistor). The second branch 120, for example, may include a second type A transistor 121 (e.g., second strong transistor) and a second type B transistor 122 (e.g., second weak transistor). In one example, the quantity of type A transistors and the quantity of type B transistors for the first branch 110 or the second branch 120 may be allocated as a partition (i.e., proportion) between type A transistors and type B transistors. In one example, the one or more of the subset of type A transistor has a larger width compared to the type B transistor. For example, if the total quantity of transistors is 100, a partition may have 95 type A transistors and 5 type B transistors.

As shown in the example of FIG. 1, the first terminals of the first branch 110 transistors may be tied to a first source voltage 115 (e.g., VDD_DOM) and the first terminals of the second branch 120 transistors may be tied to a second source voltage 125 (e.g., VDD_AUX). In addition, a first control signal 113 (e.g., enr_dom_b) may be used to enable or disable the first type A transistor 111, and a second control signal 123 (e.g., enr_aux_b) may be used to enable or disable the second type A transistor 121. In addition, a third control signal 114 (e.g., enf_dom_b) may be used to enable or disable the first type B transistor 112, and a fourth control signal 124 (e.g., enf_aux_b) may be used to enable or disable the second type B transistor 122. In one example, each control signal may be connected in series (e.g., daisy chained) with control signals from other power multiplexer tiles. In one example, each control signal may be a binary signal with two states (e.g., a first state to enable and a second state to disable).

In one example, the power multiplexer selects dc power from multiple dc power supplies. For in-rush current management during dc power supply switching, type A transistors (e.g., strong transistors) may be disabled, for example, using the first control signal 113 (e.g., enr_dom_b) and the second control signal 123 (e.g., enr_aux_b). In addition, type B transistors (e.g., weak transistors) may be enabled, for example, using the third control signal 114 (e.g., enf_dom_b) and the fourth control signal 124 (e.g., enf_aux_b). In one example, disablement of type A transistors (e.g., strong transistors) may limit the current carrying capacity of the power multiplexer. In another example, a circuit load may reduce current draw for in-rush current management during dc power supply switching (e.g., digital clock disablement, entering an idle state, etc.). In one example, current draw reduction may restrict circuit load performance (e.g., digital clock disablement may affect circuit load processing capability). In one example, buffer circuit delay may be added to the power multiplexer tiles to stagger current draw from each tile. In one example, tuning range of the buffer circuit delay may be limited for power multiplexers configured in a daisy chain which may alter the effectiveness of in-rush current management.

In one aspect, the present disclosure discloses adding a regulator and a power mux controller to the power multiplexer to manage certain transistors for in-rush current management. One skilled in the art would understand that a “power mux controller” is an abbreviation for a “power multiplexer controller”. The power multiplexer may include multiple circuit branches, where a circuit branch is a group of transistors. For example, a first circuit branch may be denoted as a “dominant” branch and a second circuit branch may be denoted as an “auxiliary” branch. One of the circuit branches may be designated as a “selected circuit branch” to be regulated by the regulator and another circuit branch may be designated as a “non-selected circuit branch” to be not regulated. In another example, both circuit branches may be designated as “selected” to be regulated.

For example, the regulator may control one circuit branch in one scenario (e.g., where one circuit branch always operates at a higher voltage than the other circuit branch), or the regulator may control both circuit branches in another scenario (e.g., where one circuit branch or the other circuit branch may operate at a higher voltage than the other at different time intervals).

In one example, the power mux controller may be a processor (e.g., microprocessor or microcontroller) for regulator operational control and management of power multiplexer input control signals. The power mux controller may implement one or more of the following regulator operational controls:

a) Regulator on/off state;

b) Regulator bypass mode; and/or

c) Regulator reference voltage selection.

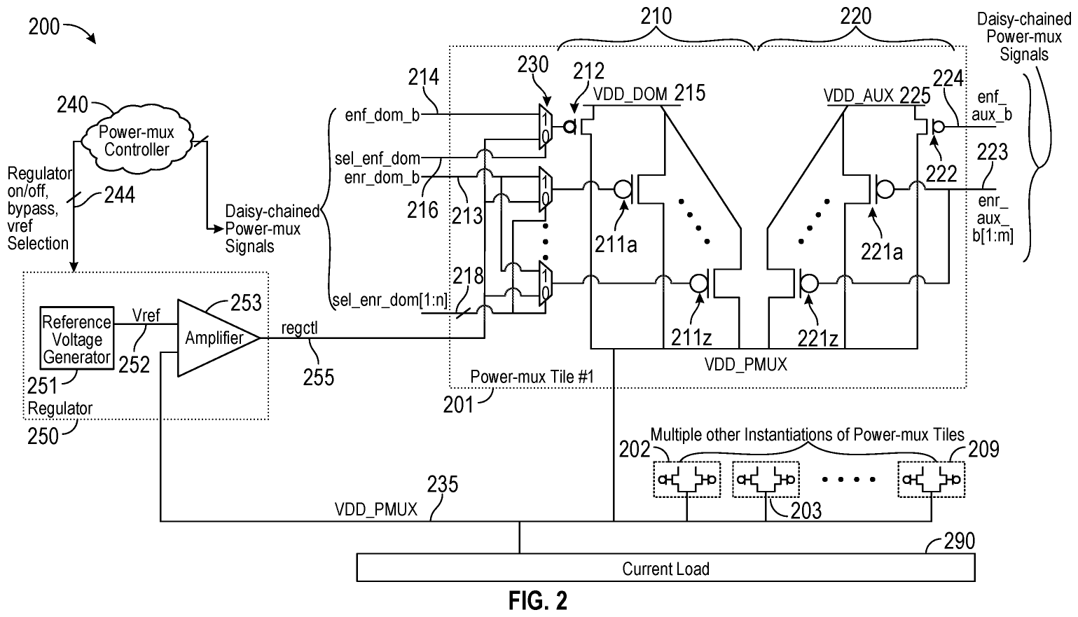

Examples of power multiplexer input control signals may include one or more of the following:
a) Enable control signal: Non-regulator control signal used to enable/disable individual transistors without regulator involvement
   e.g., enf_dom_b for “enable few” in dominant circuit branch;
      enr_dom_b for “enable rest” in dominant circuit branch;
      enf_aux_b for “enable few” in auxiliary circuit branch;
      enr_aux_b for “enable rest” in auxiliary circuit branch.
b) Regulator control signal: used to control individual transistors from regulator,
   e.g., regctl 255 in FIG. 2
c) Select control signal: used to select whether transistor control signal is from regulator or not
   e.g., sel_enf_dom being logic high for selecting non-regulator control signal in dominant circuit branch, while sel_enf_dom being logic low for selecting regulator control signal in dominant circuit branch.
      In one example, power multiplexer input control signals may be implemented in a daisy chain, i.e., in a series connection from one circuit branch to another circuit branch.

In one example, the regulator includes a reference voltage generator to generate the reference voltage Vref and an amplifier which differentially amplifies two amplifier input signals, the reference voltage Vref and a power multiplexer output voltage VDD_PMUX, to provide a regulator output. In one example, the regulator output is a regulator control signal (regctl) generated in response to the two amplifier input signals. The power mux controller may, for example, be used to control the following aspects of in-rush current management:
a) Voltage control: Sub-regulating one power mux branch to produce similar voltage as another non-regulated power mux branch
b) Current migration: Migrating current between sub-regulated and non-regulated branches
c) Rate control: Flexibly controlling rate of sub-regulating voltage change and current migration.

FIG. 2 illustrates an example of a power multiplexer system 200. In the example of FIG. 2, the power multiplexer system 200 includes a first power multiplexer tile 201. The first power multiplexer tile 201 includes a first branch 210 (e.g., dominant branch) and a second branch 220 (e.g., auxiliary branch). The first branch 210 may, for example, include a plurality of a first type A transistors 211a through 211z (e.g., first strong transistors) and a first type B transistor 212 (e.g., first weak transistor). In one example, the plurality of the first type A transistors 211a through 211z and the first type B transistor 212 may be collectively referred to as first branch transistors.

In one example, a type A transistor (e.g., strong transistor) has a lower effective resistance compared to a type B transistor (e.g., weak transistor). For example, the effective resistance difference between the two types is at least an order of magnitude difference (i.e., a factor of ten or more). In one example, a type A transistor (e.g., strong transistor) has a thinner oxide layer compared to a type B transistor (e.g., weak transistor).

The second branch 220 may, for example, include a plurality of second type A transistors 221a through 221z (e.g., second strong transistors) and a second type B transistor 222 (e.g., second weak transistor). In one example, the plurality of the second type A transistors 221a through 221z and the second type B transistor 222 may be collectively referred to as second branch transistors.

For example, first terminals of the first branch transistors may be tied to a first dc voltage 215 (e.g., VDD_DOM) and first terminals of the second branch transistors may be tied to a second dc voltage 225 (e.g., VDD_AUX). In addition, a plurality of first control signals 213 (e.g., enr_dom_b) may be used to enable or disable the plurality of the first type A transistors 211a through 211z, and a plurality of second control signals 223 (e.g., enr_aux_b) may be used to enable or disable the plurality of the second type A transistors 221a through 221z. In addition, a third control signal 214 (e.g., enf_dom_b) may be used to enable or disable the first type B transistor 212 and a fourth control signal 224 (e.g., enf_aux_b) may be used to enable or disable the second type B transistor 222. In one example, each control signal may be connected in series (e.g., daisy chained) with control signals from other power multiplexer tiles connected in series (e.g., daisy chained) with control signals for other power multiplexer tiles. In one example, each control signal may be a binary signal with two states (e.g., a first state to enable and a second state to disable).

The power multiplexer system 200 may also include a power mux controller 240 to generate control signals 213, 223, 214, 224 to enable or disable the transistors 211a . . . 211z, 221, 212a . . . 212z, 222, respectively, of the first power multiplexer tile 201. In one example, the control signals may be connected in series (e.g., daisy chained) with control signals for other power multiplexer tiles. For example, the other power multiplexer tiles are denoted as 202, 203, . . . 209 in FIG. 2. Although the other power multiplexer tiles are numbered as 202 through 209 in the example of FIG. 2, one skilled in the art would understand that the numbering is not meant to limit the quantity of the other power multiplexer tiles. That is, the quantity of power multiplexer tiles may be any number as applicable to a particular design, usage, etc. In addition, second terminals of the first branch transistors and the second branch transistors may be tied to a power rail 235 (e.g., VDD_PMUX). In one example, the power multiplexer tiles deliver electric current to a current load 290. In one example, the current load 290 is an IP current load.

The power multiplexer system 200 may also include a regulator 250. The regulator 250 may include a reference voltage generator 251 and an amplifier 253. The reference voltage generator 251 may generate a reference voltage Vref 252 which may serve as a first input to the amplifier 253. In one example, the reference voltage generator 251 may receive mode control signals 244. For example, mode control signals 244 may include a regulator on/off control signal, a regulator bypass signal, a reference voltage selection signal, etc. For example, the reference voltage selection signal may be used to set the reference voltage Vref 252 to a desired voltage level.

In one example, a second input to the amplifier 253 may be the power rail 235 (e.g., VDD_PMUX). For example, the amplifier 253 may produce a regulator output signal (regctl) 255 (a.k.a., regulated control signal). In one example, the regulator output signal (regctl) 255 may be proportional to a difference between the first input and the second input of the amplifier 253 (e.g., the difference between the reference voltage Vref 252 and the power rail 235).

In one example, a plurality of selectors 230 may be used to select whether a control signal is from the regulator 250 or not. For example, outputs of selectors 230 may be sent to third terminals of the first branch transistors to control the plurality of the first type A transistors 211a through 211z (e.g., first strong transistors) and the first type B transistor 212 (e.g., first weak transistor) of the first branch 210 of the first power multiplexer tile 201. In another example, the outputs of selectors 230 may also be sent to third terminals of the second branch transistors to control the plurality of the second type A transistors 221a through 221z (e.g. the second strong transistors) and the second type B transistor 222 (e.g. the second weak transistor) of the second branch 220.

In one example, the regulator output signal (regctl) 255 is used as a first input to the plurality of selectors 230. In one example, the plurality of first control signals 213 (e.g., enr_dom_b) or the third control signal 214 (e.g., enf_dom_b) is used as a second input to the plurality of selectors 230. In addition, a plurality of first selection signals (e.g., sel_enr_dom[1:n]) 218 and a second selection signal (e.g., sel_enf_dom) 216 may be sent to the plurality of selectors 230 to select whether a control signal is from the regulator 250 or not. In one example, the outputs of the plurality of selectors 230 may be sent to third terminals of the first branch transistors to enable or disable the plurality of the first type A transistors 211a through 211z and the first type B transistor 212 of the first branch 210 of the first power multiplexer tile 201.

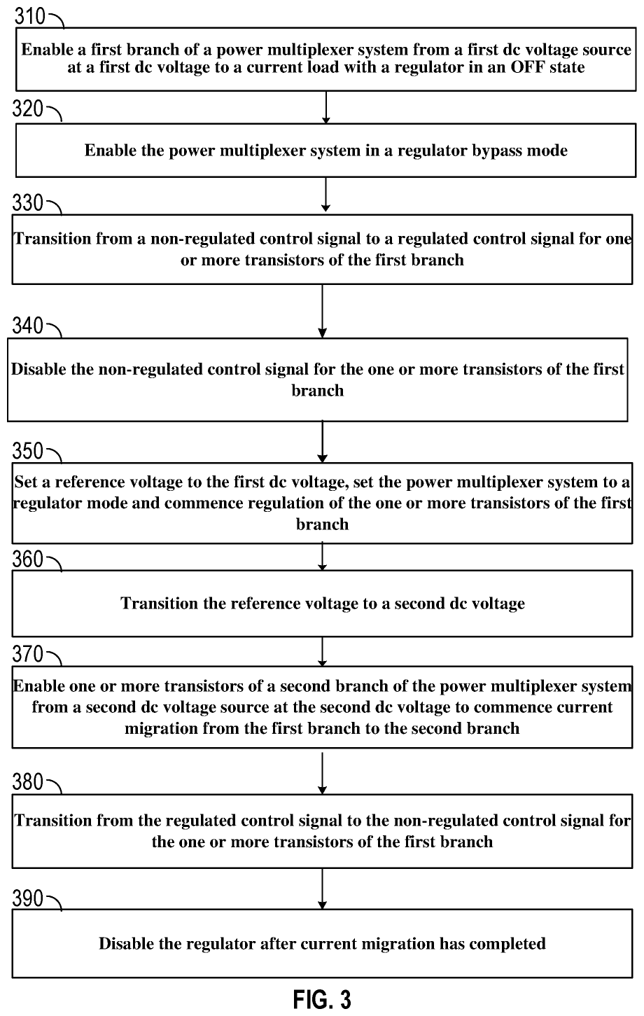

FIG. 3 illustrates an example of a flow diagram for switching from a high voltage to a low voltage. In one example, the flow diagram is implemented in a power multiplexer system with at least two branches and a regulator. In the example of FIG. 3, the first branch is the branch with the high voltage and the second branch is the branch with the low voltage at the initiation of the flow, that is, starting at block 310.

In block 310, enable a first branch of a power multiplexer system from a first dc voltage source at a first dc voltage to a current load with a regulator in an OFF state. In one example, transistors of the first branch may be controlled by non-regulated control signals (e.g., a plurality of first control signals 213 (e.g., enr_dom_b), a third control signal 214 (e.g., enf_dom_b)) from a controller. In one example, the controlling by non-regulated control signals is selected by a select control signal (e.g., 216 sel_enf_dom, 218 sel_enr_dom[1:n]. In one example, the step(s) associated with block 310 may be performed by a power mux controller (e.g., power mux controller 240 shown in FIG. 2).

In block 320, enable the power multiplexer system in a regulator bypass mode. In one example, the power multiplexer system in the regulator bypass mode configures the regulator to turn ON but without regulation activated. In one example, the step(s) associated with block 320 may be performed by a power mux controller (e.g., power mux controller 240 shown in FIG. 2).

In block 330, transition from a non-regulated control signal to a regulated control signal for one or more transistors of the first branch. In one example, the non-regulated control signal is generated by a power mux controller of the power multiplexer system. In one example, the regulated control signal is generated by the regulator. In one example, transitioning from the non-regulated control signal to the regulated control signal for one or more transistors of the first branch means to select the regulated control signal (e.g., regctl 255) from the regulator to control the one or more transistors of the first branch. In one example, the transitioning is performed using selectors 230. In one example, both the non-regulated control signal and the regulated control signal are active and may be selected by selectors 230 to control the one or more transistors. In one example, the power multiplexer system remains in regulator bypass mode while transitioning and a third terminal (e.g. gate terminal) voltage of transistors in the first branch remains constant. In one example, the step(s) associated with block 330 may be performed by a power mux controller (e.g., power mux controller 240 shown in FIG. 2).

In block 340, disable the non-regulated control signal for the one or more transistors of the first branch. In one example, the disabling occurs while the power multiplexer system remains in regulator bypass mode.

In block 350, set a reference voltage to the first dc voltage, set the power multiplexer system to a regulator mode and commence regulation of the one or more transistors of the first branch. In one example, the reference voltage is generated by the regulator. In one example, the first dc voltage is the voltage labeled as VDD_DOM 215 shown in FIG. 2. In one example, the first dc voltage is supplied to first terminals of transistors in the first branch. In one example, the regulated control signal is outputted by the regulator. In one example, the regulated control signal is generated by an amplifier within the regulator. In one example, commencing regulation of the one or more transistors of the first branch includes applying the regulated control signal to the one or more transistors of the first branch to turn them ON. In one example, the step(s) associated with block 340 may be performed by a regulator (e.g., regulator 250 shown in FIG. 2).

In block 360, transition the reference voltage to a second dc voltage. In one example, the second dc voltage is the voltage labeled as VDD_AUX 225 shown in FIG. 2. In one example, the second dc voltage is supplied to at least one of the first terminals of transistors of a second branch of the power multiplexer system. In one example, transitioning the reference voltage Vref to the second dc voltage includes sub-regulating the first branch from the first dc voltage to the second dc voltage. In one example, transitioning the reference voltage Vref to the second dc voltage includes flexibly controlling a rate of sub-regulating voltage change and current migration. In one example, flexibly controlling the rate means to adjust the rate of change at various speeds. In one example, the transition is bounded by a maximum absolute rate of change. In one example, the maximum absolute rate of change is the maximum absolute value of a first derivative of the reference voltage Vref. In one example, the transition is executed by a power mux controller. In one example, the step(s) associated with block 350 may be performed by a power mux controller (e.g., power mux controller 240 shown in FIG. 2).

In block 370, enable one or more transistors of a second branch of the power multiplexer system from a second dc voltage source at the second dc voltage to commence current migration from the first branch to the second branch. In one example, the enabling of the one or more transistors of the second branch may overlap in time with the transition step in block 350. In one example, the step(s) associated with block 360 may be performed by a power mux controller (e.g., power mux controller 240 shown in FIG. 2).

In block 380, transition from the regulated control signal to the non-regulated control signal for the one or more transistors of the first branch. In one example, the transitioning uses selectors 230 to successively reduce the current being sourced from the first branch. In one example, the transitioning of the first branch also includes powering off transistors of the first branch.

In one example, timing of block 370 and block 380 may be flexibly managed by the power multiplexer controller to migrate current from the first branch to the second branch. In one example, the rate of current migration is controlled by the power multiplexer controller. In one example, the step(s) associated with block 380 may be performed by a power mux controller (e.g., power mux controller 240 shown in FIG. 2). In one example, flexibly managing the timing may include reordering various actions disclosed in blocks 370 and 380. In one example, flexibly managing the timing may include repeating various actions disclosed in blocks 370 and 380 until current migration from the first branch to the second branch is complete.

In block 390, disable the regulator after current migration has completed. In one example, the step(s) associated with block 390 may be performed by a power mux controller (e.g., power mux controller 240 shown in FIG. 2).

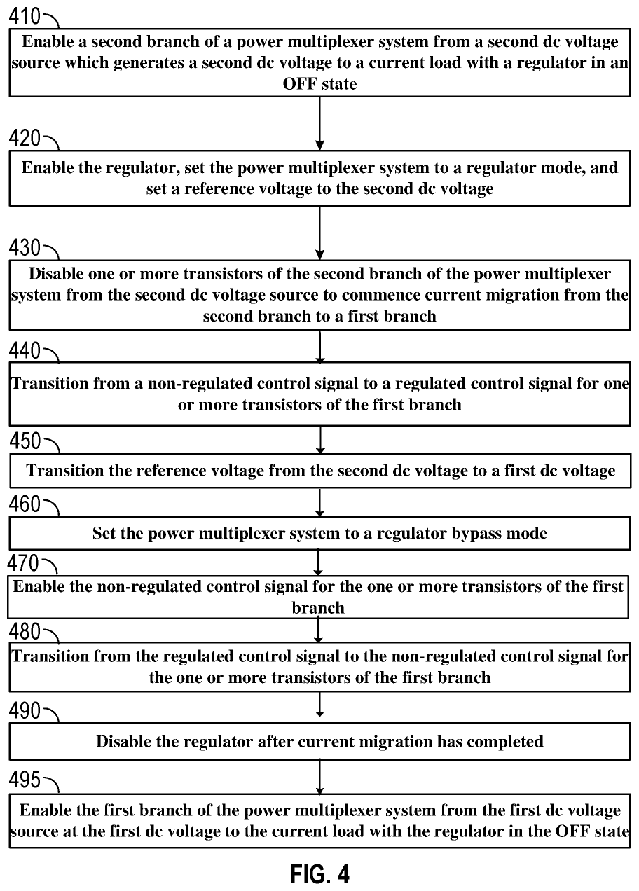

FIG. 4 illustrates an example of a flow diagram for switching from a low voltage to a high voltage. In one example, the flow diagram is implemented in a power multiplexer system with at least two branches and a regulator. In the example of FIG. 4, the second branch is the branch with the low voltage and the first branch is the branch with the high voltage at the initiation of the flow, that is, starting at block 410.

In block 410, enable a second branch of a power multiplexer system from a second dc voltage source which generates a second dc voltage (e.g., VDD_AUX) to a current load with a regulator in an OFF state. In one example, transistors of the second branch may be controlled by non-regulated control signals (e.g., 223 enr_aux_b, 224 enf_aux_b) from a controller. In one example, the step(s) associated with block 410 may be performed by a power mux controller (e.g., power mux controller 240 shown in FIG. 2).

In block 420, enable the regulator, set the power multiplexer system to a regulator mode, and set a reference voltage to the second dc voltage. In one example, a selector 230 selects non-regulated control signals for a first branch of the power multiplexer system. In one example, the step(s) associated with block 420 may be performed by a power mux controller (e.g., power mux controller 240 shown in FIG. 2).

In block 430, disable one or more transistors of the second branch of the power multiplexer system from the second dc voltage source to commence current migration from the second branch to a first branch. In one example, the disabling of one or more transistors of the second branch is performed gradually (i.e., at a limited rate of change). In one example, the limited rate of change is predetermined. In one example, the limited rate of change is a bounded absolute value of a first derivate of the current migration.

In block 440, transition from a non-regulated control signal to a regulated control signal for one or more transistors of the first branch. In one example, the transitioning is performed gradually (i.e., at a limited rate of change). In one example, the regulated control signal is generated by the power mux controller of the power multiplexer system. In one example, the regulated control signal is generated by the regulator. In one example, transitioning from the non-regulated control signal to the regulated control signal for the one or more transistors of the first branch means to select the regulated control signal (e.g., regctl 255) from the regulator to control the one or more transistors of the first branch. In one example, the transitioning is performed using selectors 230. In one example, both the non-regulated control signal and the regulated control signal are active and may be selected by selectors 230 to control the one or more transistors. In one example, the power multiplexer system remains in the regulator mode while transitioning and a third terminal (e.g., gate terminal) voltage of the one or more transistors of the first branch remains constant. In one example, being in the regulator mode include one or more of the following: voltage control: sub-regulating one power mux branch to produce similar voltage as another non-regulated power mux branch; current migration: migrating current between sub-regulated and non-regulated branches, and/or rate control: flexibly controlling rate of sub-regulating voltage change and current migration. In one example, the step(s) associated with block 440 may be performed by a power mux controller (e.g., power mux controller 240 shown in FIG. 2).

In one example, timing of block 430 and block 440 may be flexibly managed by the power multiplexer controller to migrate current from the second branch to the first branch. In one example, the rate of current migration is controlled by the power multiplexer controller. In one example, the step(s) associated with block 430 may be performed by a power mux controller (e.g., power mux controller 240 shown in FIG. 2). In one example, flexibly managing the timing may include reordering various actions disclosed in blocks 430 and 440. In one example, flexibly managing the timing may include repeating various actions disclosed in blocks 430 and 440 until current migration from the second branch to the first branch is complete.

In block 450, transition the reference voltage from the second dc voltage (e.g., VDD_AUX) to a first dc voltage. In one example, the first dc voltage is the voltage labeled as VDD_DOM 215 shown in FIG. 2. In one example, the first dc voltage is supplied to first terminals of transistors in the first branch. In one example, transitioning the reference voltage Vref to the second dc voltage includes sub-regulating the first branch from the first dc voltage to the second dc voltage. In one example, transitioning the reference voltage Vref to the first dc voltage includes flexibly controlling a rate of sub-regulating voltage change and current migration. In one example, flexibly controlling the rate means to adjust the rate of change at various speeds. In one example, the transition is bounded by a maximum absolute rate of change. In one example, the maximum absolute rate of change is the maximum absolute value of a first derivative of the reference voltage Vref. In one example, the transition is executed by a power mux controller. In one example, the step(s) associated with block 450 may be performed by a power mux controller (e.g., power mux controller 240 shown in FIG. 2).

In block 460, set the power multiplexer system to a regulator bypass mode. In one example, the selector 230 selects the regulated control signal in the regulator bypass mode.

In block 470, enable the non-regulated control signal for the one or more transistors of the first branch. In one example, the selector 230 selects the regulated control signal in the regulator bypass mode.

In block 480, transition from the regulated control signal to the non-regulated control signal for the one or more transistors of the first branch. In one example, the transitioning uses selectors 230 to successively reduce the current being sourced from the second branch.

In block 490, disable the regulator after current migration has completed. In one example, the step(s) associated with block 480 may be performed by a power mux controller (e.g., power mux controller 240 shown in FIG. 2).

In block 495, enable the first branch of the power multiplexer system from the first dc voltage source at the first dc voltage to the current load with the regulator in the OFF state.

In one aspect, one or more of the steps for switching voltages (e.g., switching from a high voltage to a low voltage or switching from a low voltage to a high voltage in FIGS. 3 and 4 respectively may be executed by one or more processors which may include hardware, software, firmware, etc. In one aspect, one or more of the steps in FIG. 3 or FIG. 4 may be executed by one or more processors which may include hardware, software, firmware, etc. The one or more processors, for example, may be used to execute software or firmware needed to perform the steps in the flow diagrams of FIG. 3 and/or FIG. 4. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in the processing system, external to the processing system, or distributed across multiple entities including the processing system. The computer-readable medium may be embodied in a computer program product. By way of example, a computer program product may include a computer-readable medium in packaging materials. The computer-readable medium may include software or firmware for switching voltages, migrating current or controlling rates in a power multiplexer system. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

What is claimed is:

1. A power multiplexer (mux) system comprising:
a power mux controller, wherein the power mux controller generates at least one non-regulated control signal;
a regulator coupled to the power mux controller, wherein the regulator generates a reference voltage and wherein the reference voltage is used for generating a regulated control signal; and
at least one power multiplexer tile coupled to the regulator, wherein each of the at least one power multiplexer tile includes a first branch comprising a first plurality of transistors and a second branch comprising a second plurality of transistors, and wherein enabling or disabling one or more of the first plurality of transistors is based on either the at least one non-regulated control signal or the regulated control signal.

2. The power multiplexer system of claim 1, wherein the at least one non-regulated control signal enables or disables one or more of the second plurality of transistors.

3. The power multiplexer system of claim 2, wherein the regulator comprises a reference voltage generator and an amplifier.

4. The power multiplexer system of claim 3, wherein the reference voltage generator generates the reference voltage that serves as a first input to the amplifier.

5. The power multiplexer system of claim 4, wherein the reference voltage generator receives at least one mode control signal from the power mux controller.

6. The power multiplexer system of claim 5, wherein the amplifier generates the regulated control signal as an output.

7. The power multiplexer system of claim 5, wherein the at least one mode control signal includes one or more of the following: a regulator on/off control signal, a regulator bypass signal, and a reference voltage selection signal.

8. The power multiplexer system of claim 7, wherein the reference voltage is used to set a desired voltage level.

9. A method for switching from a high voltage to a low voltage comprising:
setting a reference voltage to a first dc voltage;
commencing regulation of one or more transistors of a first branch of a power multiplexer system and setting the power multiplexer system to a regulator mode;
transitioning the reference voltage to a second dc voltage;
enabling one or more transistors of a second branch of the power multiplexer system from a second dc voltage source at the second dc voltage to commence current migration from the first branch to the second branch; and
transitioning from a regulated control signal to a non-regulated control signal for the one or more transistors of the first branch.

10. The method of claim 9, further comprising enabling the first branch from a first dc voltage source at the first dc voltage to a current load with a regulator in an OFF state.

11. The method of claim 10, wherein the regulator generates the regulated control signal.

12. The method of claim 10, further comprising enabling the power multiplexer system in a regulator bypass mode.

13. The method of claim 12, wherein the power multiplexer system in the regulator bypass mode configures the regulator to turn ON without applying the regulated control signal to the one or more transistors of the first branch.

14. The method of claim 12, further comprising transitioning from the non-regulated control signal to the regulated control signal for the one or more transistors of the first branch.

15. The method of claim 14, further comprising disabling the non-regulated control signal for the one or more transistors of the first branch.

16. The method of claim 15, further comprising disabling the regulator after current migration has completed.

17. The method of claim 9, wherein the regulation of the one or more transistors of the first branch includes one or more of the following: voltage control, current migration, and rate control.

18. The method of claim 9, wherein the transitioning the reference voltage to the second dc voltage is bounded by a maximum absolute rate of change.

19. The method of claim 18, wherein the maximum absolute rate of change is a maximum absolute value of a first derivative of the reference voltage.

20. A method for switching from a low voltage to a high voltage comprising:
enabling a regulator in a power multiplexer system and setting the power multiplexer system to a regulator mode;
setting a reference voltage to a first dc voltage;
disabling one or more transistors of a first branch of the power multiplexer system from the first dc voltage source to commence current migration from the first branch to a second branch of the power multiplexer system;
transitioning from a non-regulated control signal to a regulated control signal for one or more transistors of the second branch; and
transitioning the reference voltage from the first dc voltage to a second dc voltage.

21. The method of claim 20, wherein the disabling the one or more transistors of the first branch is performed at a limited rate of change.

22. The method of claim 21, wherein the limited rate of change is a bounded absolute value of a first derivative of the current migration.

23. The method of claim 20, wherein the regulated control signal is generated by the regulator.

24. The method of claim 23, wherein the transitioning from the non-regulated control signal to the regulated control signal for the one or more transistors of the second branch comprises selecting the regulated control signal from the regulator to control the one or more transistors of the second branch.

25. The method of claim 20, wherein the regulator mode includes one or more of the following: voltage control, current migration, and rate control.

26. The method of claim 20, further comprising enabling the first branch from a first dc voltage source which generates the first dc voltage to a current load with the regulator in an OFF state.

27. The method of claim 26, further comprising setting the power multiplexer system to a regulator bypass mode and enabling the non-regulated control signal for the one or more transistors of the second branch.

28. The method of claim 27, further comprising transitioning from the regulated control signal to the non-regulated control signal for the one or more transistors of the second branch.

29. The method of claim 28, further comprising disabling the regulator after current migration has completed and enabling the second branch from the second dc voltage source at the second dc voltage to the current load with the regulator in the OFF state.

30. A computer-readable medium storing computer executable code, operable on a device comprising at least one processor and at least one memory coupled to the at least one processor, wherein the at least one processor is configured to implement switching from a high voltage to a low voltage, the computer executable code comprising:
instructions for causing a computer to set a reference voltage to a first dc voltage;
instructions for causing the computer to commence regulation of one or more transistors of a first branch of a power multiplexer system and setting the power multiplexer system to a regulator mode;
instructions for causing the computer to transition the reference voltage to a second dc voltage;
instructions for causing the computer to enable one or more transistors of a second branch of the power multiplexer system from a second dc voltage source at the second dc voltage to commence current migration from the first branch to the second branch; and
instructions for causing the computer to transition from a regulated control signal to a non-regulated control signal for the one or more transistors of the first branch.
